(19) United States
(12) Patent Application Publication
(10) Pub. No.: US 2024/0113725 A1
(43) Pub. Date: Apr. 4, 2024

(54) EMBEDDED SAR-ADC WITH LEAST SIGNIFICANT BIT SKIPPING BASED RELU ACTIVATION FUNCTION

(71) Applicant: Intel Corporation, Santa Clara, CA (US)

(72) Inventors: Hechen Wang, Portland, OR (US); Renzhi Liu, Portland, OR (US); Richard Dorrance, Hillsboro, OR (US); Deepak Dasalukunte, Beaverton, OR (US); Brent Carlton, Portland, OR (US)

(21) Appl. No.: 18/539,957

(22) Filed: Dec. 14, 2023

Related U.S. Application Data
(60) Provisional application No. 63/580,604, filed on Sep. 5, 2023.

(51) Int. Cl. H03M 1/46; G11C 7/16

(52) U.S. Cl. CPC H03M 1/466; G11C 7/16; H03M 1/462

(57) ABSTRACT

Systems, apparatuses and methods may provide for technology that includes a capacitor ladder, a plurality of memory cells coupled to the capacitor ladder, the plurality of memory cells to control the capacitor ladder to conduct multi-bit multiply accumulate (MAC) operations during a computation phase, and a successive approximation register (SAR) coupled to the capacitor ladder, the SAR to control the capacitor ladder to digitize results of the multi-bit MAC operations during a digitization phase.

### CROSS-REFERENCE TO RELATED APPLICATIONS

The present application claims the benefit of priority to U.S. Provisional Patent Application No. 63/580,604, filed on Sep. 5, 2023.

### BACKGROUND

There may be an increased emphasis on quantized integer data formats such as 4-bit integer (INT4) and 8-bit integer (INT8) to address the growing size of artificial intelligence (AI) models. With the reduced precision introduced by INT4/INT8 formats, analog compute-in-memory (ACiM) has demonstrated the potential to handle transformers and recurrent neural network (RNN)-transducers with greater efficiency. There remains considerable room for improvement, however, with analog to digital converter (ADC) and digital to analog converter (DAC) operations in ACiM architecture with respect to power consumption and latency.

### BRIEF DESCRIPTION OF THE DRAWINGS

The various advantages of the embodiments will become apparent to one skilled in the art by reading the following specification and appended claims, and by referencing the following drawings, in which:

FIG. 1A is an illustration of an example of a power and latency distribution for a conventional analog compute-in-memory (ACiM) neural network;

FIG. 1B is a block diagram of an example of a conventional ACiM architecture;

FIG. 2 is a die photo and a schematic diagram of an example of a conventional ACiM architecture;

FIG. 3 is a schematic diagram of an example of a capacitor ladder during a computation phase and a digitization phase according to an embodiment;

FIG. 4 is a schematic diagram of an example of a multi-bit in-memory multiply and accumulate (MAC) unit according to an embodiment;

FIG. 5 is a schematic diagram of an example of an embedded successive approximation register (SAR)-ADC according to an embodiment;

FIG. 6 is an illustration of an example of a timing diagram according to an embodiment;

FIG. 7 is a schematic diagram of an example of a least significant bit (LSB) skipping solution according to an embodiment;

FIG. 8 is a flowchart of an example of a method of operating a performance-enhanced computing system according to an embodiment;

FIG. 9 is a flowchart of an example of a method of selectively digitizing results of multi-bit MAC operations according to an embodiment;

FIG. 10 is a block diagram of an example of a performance-enhanced computing system according to an embodiment;

FIG. 11 is an illustration of an example of a semiconductor package apparatus according to an embodiment.

### DETAILED DESCRIPTION

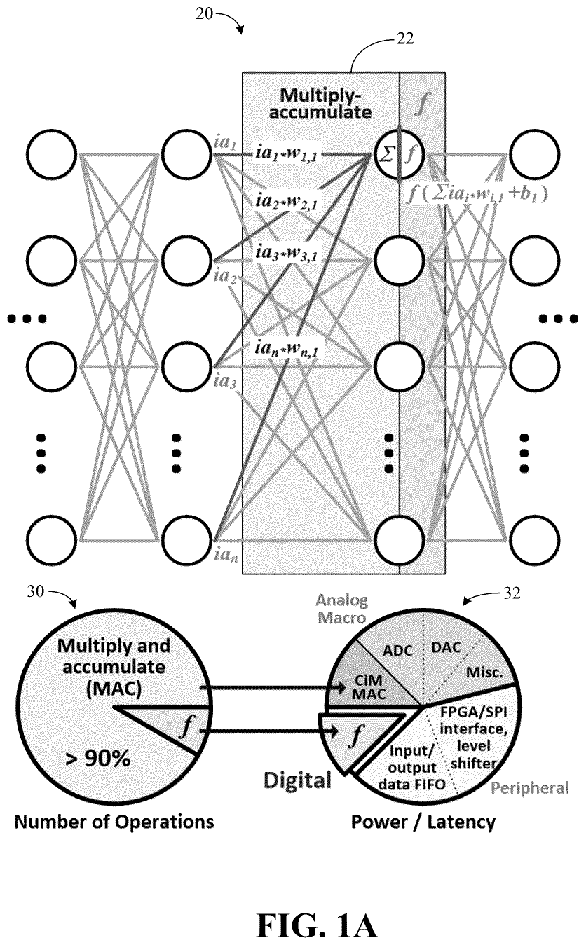

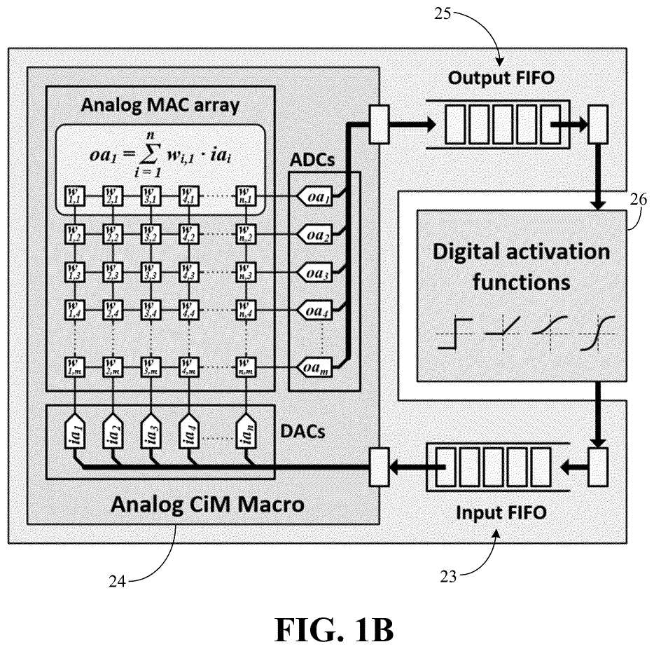

Turning now to FIGS. 1A and 1B, a neural network (NN) 20 is shown, wherein the neural network 20 includes a multiply and accumulate (MAC) layer 22. The illustrated MAC layer 22 multiplies input activations (ia) by weights (w), sums the products and applies an activation function (ƒ) to the summation results. Most existing ACiMs only focus on the multiply and accumulate (MAC) operation, relegating the activation function to the digital domain. Thus, an analog CiM macro 24 retrieves digital input activation data from an input FIFO 23 (first in first out buffer), converts the digital input activation data to analog via digital to analog converters (DACs), conducts the MAC operations to obtain output activations (oa), converts the output activations to digital via digital to analog converters (ADCs), and writes the digital results to an output FIFO 25. Activation functions 26 are applied to the contents of the output FIFO 25 in the digital domain.

Thus, because the MAC operations and the activation functions 26 are in different domains, frequent data conversion is conducted. The power and area overhead of the ADCs and DACs is significant (e.g., becoming a new bottleneck). Moreover, the ADCs and DACs typically use buffering and calibration, which lowers the efficiency, throughput and robustness. A first chart 30 demonstrates that the activation functions 26 account for less than 10% of the total number of operations in the neural network 20, whereas a second chart 32 demonstrates that the frequent data conversion between analog and digital domains, along with the data movement overhead, the benefits obtained by analog computing are greatly reduced or even neutralized.

### Overview

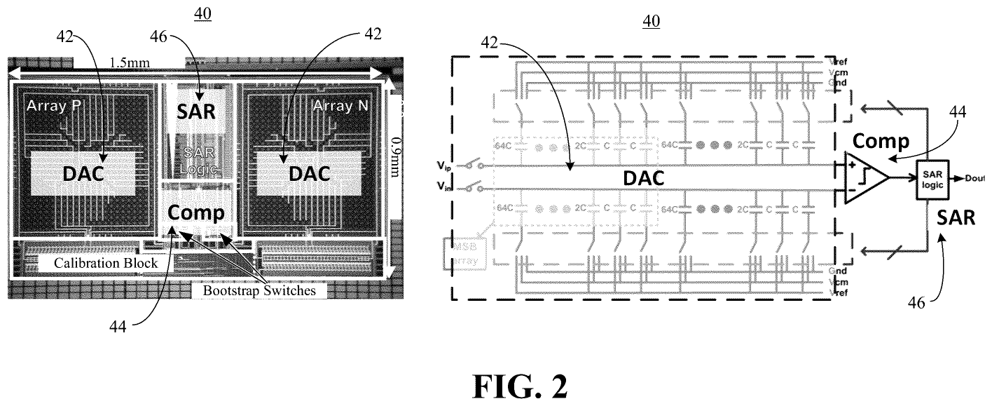

Turning now to FIG. 2, most CiM solutions use a successive approximation register (SAR) ADC 40 due to power-efficiency. A traditional SAR ADC 40 consists of a DAC 42 to convert a digital code to a reference voltage, a comparator 44 to determine the relation between the input voltage and the referenced voltage generated by the DAC 42, and SAR logic 46 to control the DAC 42 to generate the reference voltage based on the decision of the previous cycle. In the illustrated example, the DAC 42 dominates the overall area and power of the SAR ADC 40 design.

The technology described herein provides an embedded SAR-ADC that enables in-memory capacitor ladders to sample and store the charge on the combined output node during MAC operation. The same ladders are then reused for digitization. Add-on parts to build an ADC as described herein are a comparator and SAR logic, involving only limited area and power usage.

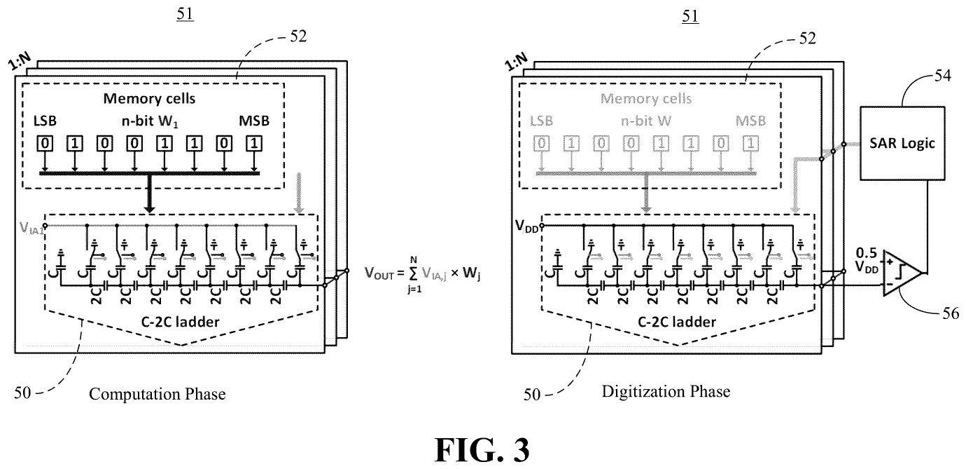

As shown in FIG. 3, during a computation phase of a CiM array 51, a capacitor (e.g., C-2C) ladder 50 is controlled by memory (e.g., static random access memory/SRAM) cells 52 to perform multi-bit MAC operations. After the computation is done, the CiM array 51 then enters a digitization phase, where all the capacitor ladders 50 are merged together and the control is switched to a centralized SAR logic 54 block. With this capacitor ladder 50 re-use, the only additional blocks in the CiM array 51 are the SAR logic 54 and a comparator 56, which only occupy an area less than ⅕ of a standalone SAR ADC. With this proposed scheme, the overall area and power efficiency of the CiM macro can be greatly improved. Additionally, rectified linear unit (ReLU) activation is realized by a least significant bit (LSB) “skipping” scheme in the SAR-ADC topology to further reduce the data conversion overhead.

Advantages of the technology described herein include area efficient digitization without the overhead of a full-fledged ADC. The capacitive DACs are the most area intensive part of SAR-ADCs and the elimination of such DACs by re-use of capacitors from the analog mixed-signal (AMS) array lowers area usage as a multitude of ADC instances are used for the CiM based system.

Additionally, embodiments offer scalability with cheaper conversion when a data is converted into digital representation for long distance communication. This condition is especially true for communications in a relatively large chip where analog domain representation is impractical (e.g., data is converted to digital domain and transferred using packets over a chip). Moreover, the LSB skipping based ReLU activation can lower the power consumption of the ADC significantly (e.g., 40%-50%).

One or more embodiments result in a regular C-2C memory array structure and a C-2C ladder CiM with digitization logic containing only one set of capacitors and no capacitors for the SAR-ADC. One or more embodiments also include a unique overlapping structure of passive metal-oxide-metal (MOM) capacitors above a standard memory cell active region.

Details

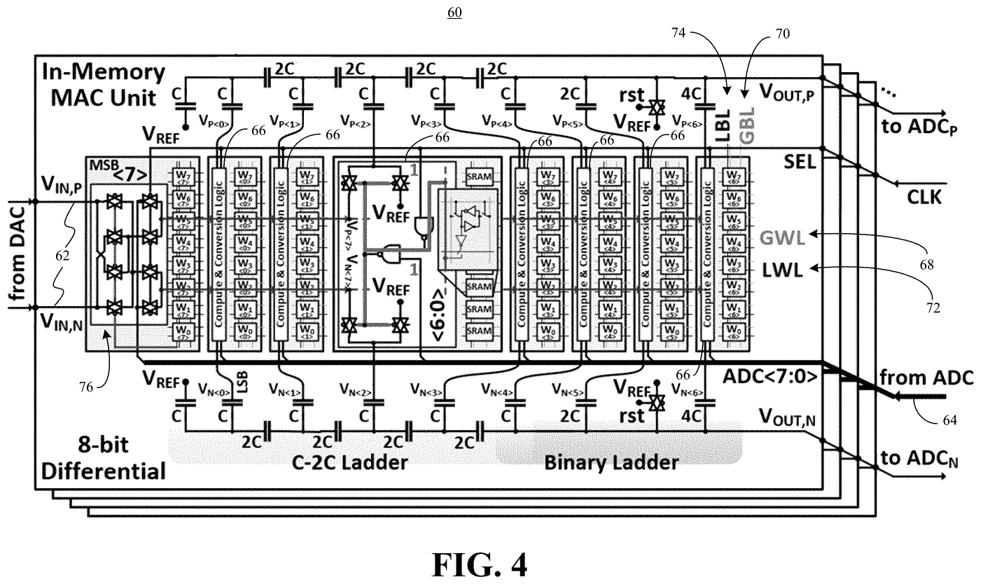

FIG. 4 shows an 8-bit in-memory MAC unit 60 based on a hybrid differential capacitor ladder. Bit cells <6:0> are identical and contain local in-memory compute & conversion logic 66 (with bit <2> shown in detail) to modulate the ladder by selecting either NN weights (e.g., w₀ to w₇) stored in SRAM during the MAC computing phase or an ADC feedback signal 64 during the data conversion phase to control a pass-gate MUX (multiplexer) in each capacitor branch on the ladder. Eight 9T (nine transistor) SRAM cells are grouped for each bit, providing eight sets of weights to improve the in-memory weight storage volume. To isolate the original global wordlines (GWLs) 68 and global bitlines (GBLs) 70, local wordlines (LWLs) 72 and local bitlines (LBLs) 74 are added to select the target weight bank in each cycle for each MAC unit 60. The MUX switches the signal between the input voltage 62 (VIN,P/N) and the virtual ground of the differential rails, VREF (e.g., equal to half VDD). Then, in the computation phase, the product of the input voltage 62 and the NN weight is available at the output of the ladder (VOUT,P/N). A butterfly switch 76 alters the input voltage 62 and feeds to the differential rails based on the sign-bit (MSB<7>) to realize a Sign-Mag INT-8 format. In this arrangement, the error due to capacitor mismatch is aligned with typical NN weight distributions, which ensures better accuracy. The outputs of multiple MAC units 60 are connected for charge summation and fed to the ADC.

ADCs are the top power and area consumer in many conventional ACiMs. As already noted, the technology described herein includes an embedded SAR-ADC that enables in-memory capacitor ladders to sample and store the charge on the combined output node during MAC operation, and then the same ladders are reused to conduct digitization. The additional components of the ADC are a comparator and SAR logic, which use only limited area and power.

Buffers are traditionally used between the CiM output and the ADC to enhance the signal, lower the impact of the parasitic capacitances, and reduce kickback noise introduced by the comparator. In the technology described herein, no buffer is added as the total capacitance is large enough to ignore those effects. Furthermore, since the capacitors used for digitization are the same during MAC computing, errors generated during those two operations are automatically cancelled. Thus, no calibration or compensation is conducted.

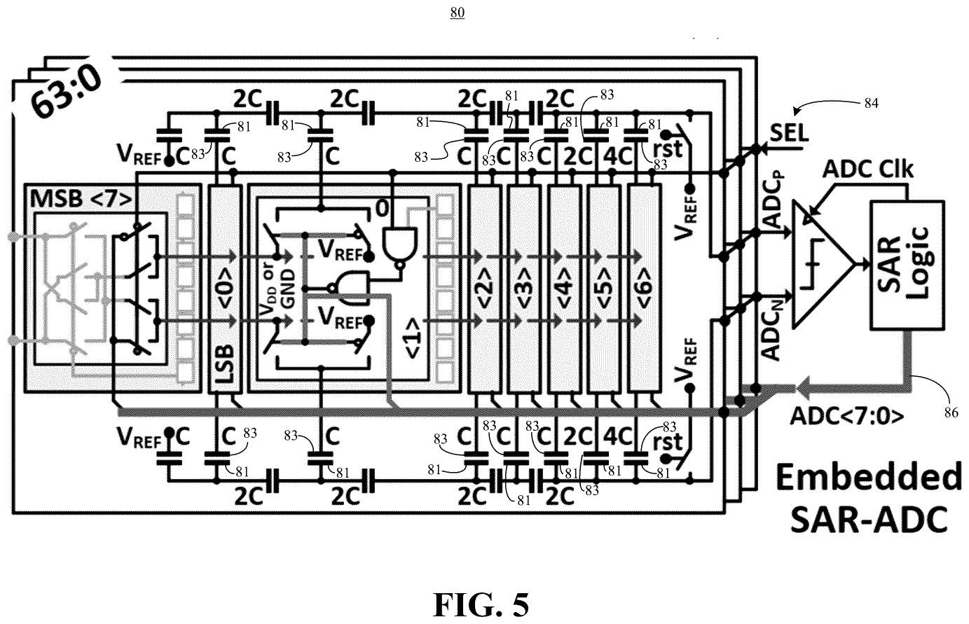

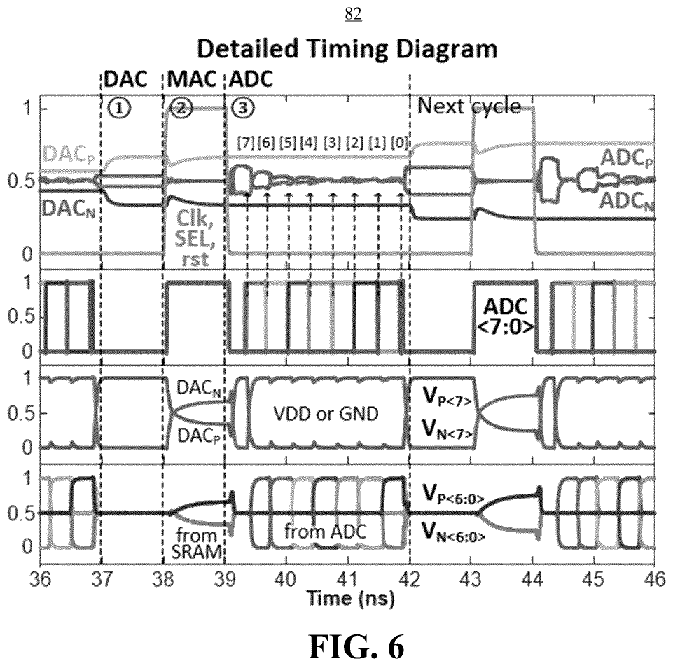

Turning now to FIGS. 5 and 6, an embedded SAR-ADC 80 and corresponding simulated timing diagram 82 are shown to illustrate the operation. Bit <2> of the embedded SAR-ADC is shown in detail and one complete cycle may consist of three phases.

Phase 1 (DAC phase) starts each time after the previous ADC conversion is completed. DACs fetch new data from the input activation buffer and generate corresponding differential analog output DACP/N. In the meantime, the MAC unit selects one of the eight SRAM banks and connects to the Compute & Conversion Logic.

Phase 2 (MAC phase) starts at the clock-raising edge. The clock signal serves as the “rst” (reset) signal of the top plates 81 of the capacitor ladders and the “SEL” (select) signal 84 indicates whether the ladder is controlled by the SRAM or the ADC feedback. The top plates 81 of the capacitor ladders are reset to virtual ground (VREF). The ADC feedback signal ADC<7:0> and the “SEL” signal 84 are forced to “1” (see, FIG. 3) to initiate control of the capacitor ladder by the SRAM. The bottom plates 83 on the capacitor ladder (VP/N<6:0>) are connected to DACP/N or VREF. The polarity of DACP/N is determined by the MSB of the data through VP/N<7>. MAC computing is essentially an RC (resistor-capacitor) network charging process.

Phase 3 (ADC phase) starts when the charging is fully settled. The “SEL” signal 84 and the “rst” signal are set to “0”, and all 64 differential ladders are then controlled by the same set of SAR logic signals 86 (ADC<7:0>). VP/N<7> in this phase is switched from DACP/N to the power rails (VDD and GND). Thus, the ladder is selected between power and VREF. The digitization result is available after eight ADC internal clock cycles.

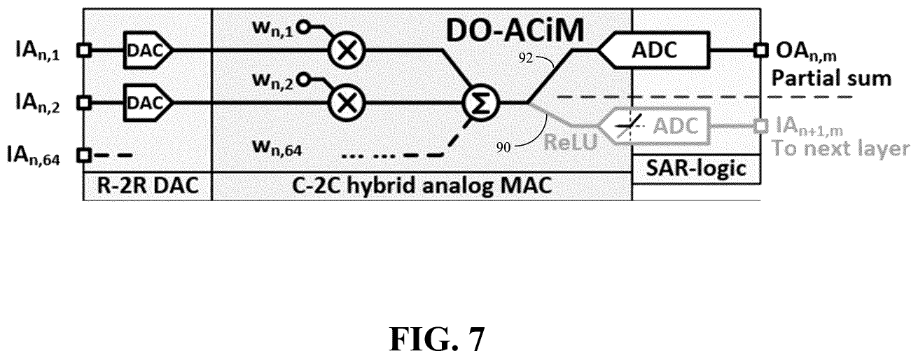

Turning now to FIG. 7, ReLU can be realized with SAR-ADC LSB skipping. In general, a rectified linear unit (ReLU) is an activation function that introduces the property of non-linearity to a deep learning model and solves a vanishing gradients issue. The ReLU activation function interprets the positive part of its respective argument (e.g., all negative values default to zero, and the maximum for the positive number is taken into consideration). Under the technology described herein, once the first SAR comparison is completed, the polarity is revealed. Accordingly, the conversion can be stopped on path 90 if the result is negative or continued on path 92 if positive. As the output is evenly distributed around zero, this scheme can lower the power by more than 40%, with acceptable accuracy.

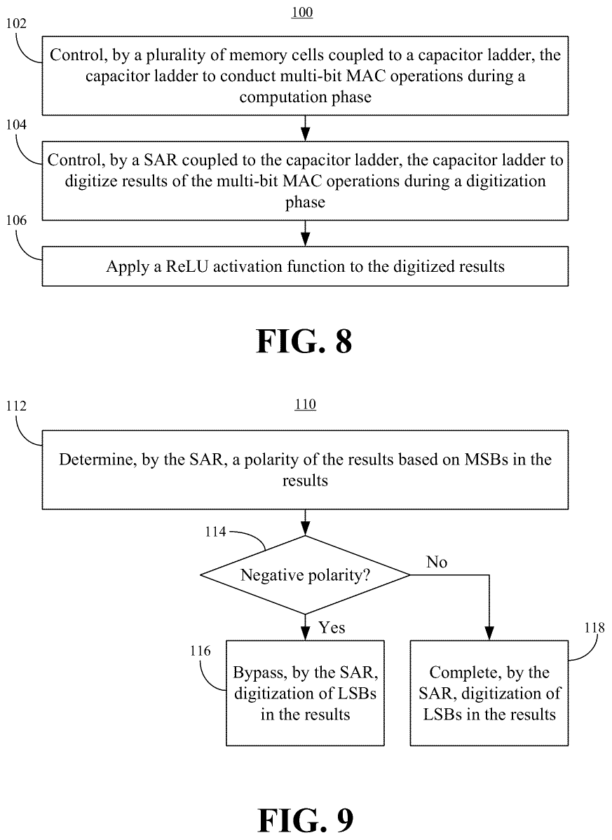

FIG. 8 shows a method 100 of operating a performance-enhanced computing system. The method 100 may generally be implemented in a CiM array such as, for example, the CiM array 51 (FIG. 3), already discussed. More particularly, the method 100 may be implemented in one or more modules as a set of logic instructions (e.g., executable program instructions) stored in a machine- or computer-readable storage medium such as random access memory (RAM), read only memory (ROM), programmable ROM (PROM), firmware, flash memory, etc., in hardware, or any combination thereof. For example, hardware implementations may include configurable logic, fixed-functionality logic, or any combination thereof. Examples of configurable logic (e.g., configurable hardware) include suitably configured programmable logic arrays (PLAs), field programmable gate arrays (FPGAs), complex programmable logic devices (CPLDs), and general purpose microprocessors. Examples of fixed-functionality logic (e.g., fixed-functionality hardware) include suitably configured application specific integrated circuits (ASICs), combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

Illustrated processing block 102 controls, by a plurality of memory cells coupled to a capacitor ladder (e.g., C-2C) ladder, the capacitor ladder to conduct multi-bit MAC operations during a computation phase. Block 104 controls, by a SAR coupled to the capacitor ladder, the capacitor ladder to digitize results of the multi-bit MAC operations during a digitization phase. In one example, block 104 digitizes the results of the multi-bit MAC operations via a comparator. In an embodiment, block 106 applies a ReLU activation function to the digitized results. The method 100 therefore performance results at least to the extent that using the same capacitor ladder to conduct the multi-bit MAC operations and digitize the results of the multi-bit MAC operations reduces area and/or power overhead and improves scalability (e.g., in long distance communication environments such as large chips). The method 100 also improves efficiency, throughput and robustness by eliminating buffering and calibration associated with conventional ADC and DAC operations.

FIG. 9 shows a method 110 of selectively digitizing results of multi-bit MAC operations. The method 110 may generally be incorporated into block 104 (FIG. 8), already discussed. More particularly, the method 110 may be implemented in one or more modules as a set of logic instructions stored in a machine- or computer-readable storage medium such as RAM, ROM, PROM, firmware, flash memory, etc., in hardware, or any combination thereof.

Illustrated processing block 112 provides for determining, by the SAR, a polarity of the results of the multi-bit MAC operations based on MSBs in the results. A determination may be made at block 114 as to whether the polarity is negative. If so, block 116 bypasses, by the SAR, digitization of LSBs in the results. Otherwise, block 118 completes digitization of the LSBs in the results. The method 110 therefore further enhances performance at least to the extent that bypassing digitization of the LSBs further reduces power consumption.

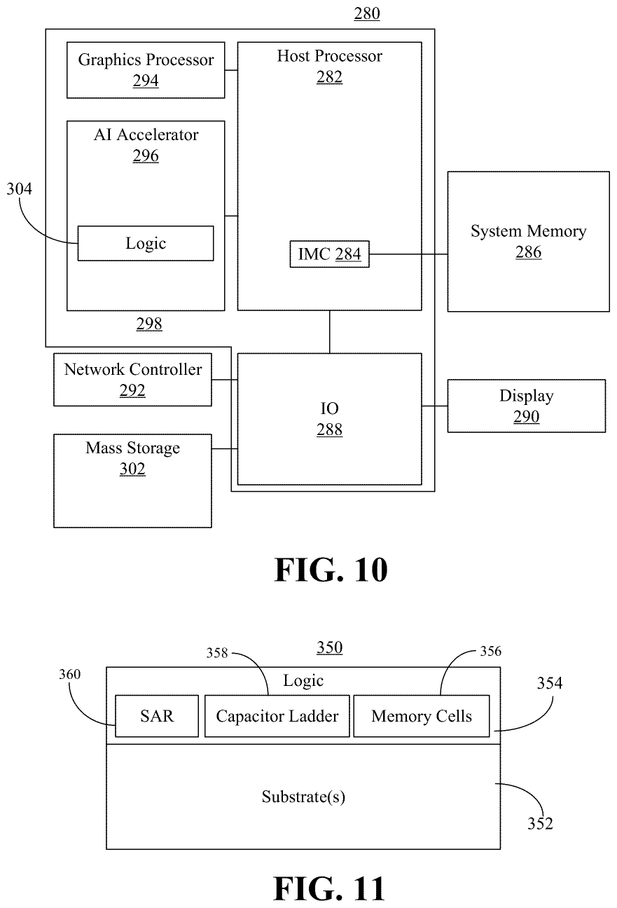

Turning now to FIG. 10, a performance-enhanced computing system 280 is shown. The system 280 may generally be part of an electronic device/platform having computing functionality (e.g., personal digital assistant/PDA, notebook computer, tablet computer, convertible tablet, edge node, server, cloud computing infrastructure), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), Internet of Things (IoT) functionality, drone functionality, etc., or any combination thereof.

In the illustrated example, the system 280 includes a host processor 282 (e.g., central processing unit/CPU) having an integrated memory controller (IMC) 284 that is coupled to a system memory 286 (e.g., dual inline memory module/DIMM including a plurality of DRAMs). In an embodiment, an IO (input/output) module 288 is coupled to the host processor 282. The illustrated IO module 288 communicates with, for example, a display 290 (e.g., touch screen, liquid crystal display/LCD, light emitting diode/LED display), mass storage 302 (e.g., hard disk drive/HDD, optical disc, solid state drive/SSD) and a network controller 292 (e.g., wired and/or wireless). The host processor 282 may be combined with the IO module 288, a graphics processor 294, and an artificial intelligence (AI) accelerator 296 (e.g., specialized processor) into a system on chip (SoC) 298.

The illustrated AI accelerator 296 includes logic 304 including a CiM array such as, for example, the CiM array 51 (FIG. 3), already discussed. In one example, the logic 304 performs one or more aspects of the method 100 (FIG. 8) and/or the method 110 (FIG. 9), already discussed. Thus, the logic 304 includes a capacitor ladder and a plurality of memory cells coupled to the capacitor ladder, wherein the plurality of memory cells are to control the capacitor ladder to conduct multi-bit MAC operations during a computation phase. The logic 304 also includes a SAR coupled to the capacitor ladder, wherein the SAR is to control the capacitor ladder to digitize results of the multi-bit MAC operations during a digitization phase. The computing system 280 is therefore considered to be performance-enhanced at least to the extent that using the same capacitor ladder to conduct the multi-bit MAC operations and digitize the results of the multi-bit MAC operations reduces area and/or power overhead and improves scalability (e.g., in long distance communication environments such as large chips). The computing system 280 also achieves improved efficiency, throughput and robustness associated with the elimination of buffering and calibration associated with conventional ADC and DAC operations.

FIG. 11 shows a semiconductor apparatus 350 (e.g., chip, die, package). The illustrated apparatus 350 includes one or more substrates 352 (e.g., silicon, sapphire, gallium arsenide) and logic 354 (e.g., transistor array and other integrated circuit/IC components) coupled to the substrate(s) 352. The logic 354 can be readily substituted for the logic 304 (FIG. 10), already discussed. In an embodiment, the logic 354 implements one or more aspects of the method 100 (FIG. 8) and/or the method 110 (FIG. 9), already discussed. Thus, the logic 354 includes a capacitor ladder 358 (e.g., C-2C ladder) and a plurality of memory cells 356 coupled to the capacitor ladder 358, wherein the plurality of memory cells 356 are to control the capacitor ladder 358 to conduct multi-bit MAC operations during a computation phase. The logic 354 also includes a SAR 360 coupled to the capacitor ladder 358 to digitize results of the multi-bit MAC operations during a digitization phase.

The logic 354 may be implemented at least partly in configurable or fixed-functionality hardware. In one example, the logic 354 includes transistor channel regions that are positioned (e.g., embedded) within the substrate(s) 352. Thus, the interface between the logic 354 and the substrate(s) 352 may not be an abrupt junction. The logic 354 may also be considered to include an epitaxial layer that is grown on an initial wafer of the substrate(s) 352.

### Additional Notes and Examples

Example 1 includes a computing system comprising a network controller, and a processor coupled to the network controller, wherein the processor includes logic coupled to one or more substrates, the logic including a capacitor ladder, a plurality of memory cells coupled to the capacitor ladder, the plurality of memory cells to control the capacitor ladder to conduct multi-bit multiply and accumulate (MAC) operations during a computation phase, and a successive approximation register (SAR) coupled to the capacitor ladder, the SAR to control the capacitor ladder to digitize results of the multi-bit MAC operations during a digitization phase.

Example 2 includes the computing system of Example 1, wherein the logic further includes a comparator coupled to the capacitor ladder and the SAR, wherein the results of the multi-bit MAC operations are to be digitized via the comparator.

Example 3 includes the computing system of Example 1, wherein the logic is to apply a rectified linear unit activation function to the digitized results.

Example 4 includes the computing system of any one of Examples 1 to 3, wherein the SAR is to determine a polarity of the results based on most significant bits in the results.

Example 5 includes the computing system of Example 4, wherein the SAR is to bypass digitization of least significant bits in the results if the polarity is negative.

Example 6 includes the computing system of Example 4, wherein the SAR is to complete digitization of least significant bits in the results if the polarity is positive.

Example 7 includes the computing system of any one of Examples 1 to 6, wherein the capacitor ladder includes a C-2C ladder.

Example 8 includes a semiconductor apparatus comprising one or more substrates, and logic coupled to the one or more substrates, wherein the logic is implemented at least partly in one or more of configurable or fixed-functionality hardware, the logic including a capacitor ladder, a plurality of memory cells coupled to the capacitor ladder, the plurality of memory cells to control the capacitor ladder to conduct multi-bit multiply and accumulate (MAC) operations during a computation phase, and a successive approximation register (SAR) coupled to the capacitor ladder, the SAR to control the capacitor ladder to digitize results of the multi-bit MAC operations during a digitization phase.

Example 9 includes the semiconductor apparatus of Example 8, further including a comparator coupled to the capacitor ladder and the SAR, wherein the results of the multi-bit MAC operations are to be digitized via the comparator.

Example 10 includes the semiconductor apparatus of Example 8, wherein the logic is to apply a rectified linear unit activation function to the digitized results.

Example 11 includes the semiconductor apparatus of any one of Examples 8 to 10, wherein the SAR is to determine a polarity of the results based on most significant bits in the results.

Example 12 includes the semiconductor apparatus of Example 11, wherein the SAR is to bypass digitization of least significant bits in the results if the polarity is negative.

Example 13 includes the semiconductor apparatus of Example 11, wherein the SAR is to complete digitization of least significant bits in the results if the polarity is positive.

Example 14 includes the semiconductor apparatus of any one of Examples 8 to 13, wherein the capacitor ladder includes a C-2C ladder.

Example 15 includes the semiconductor apparatus of any one of Examples 8 to 13, wherein the logic coupled to the one or more substrates includes transistor channel regions that are positioned within the one or more substrates.

Example 16 includes a method of operating a performance-enhanced computing system, the method comprising controlling, by a plurality of memory cells coupled to a capacitor ladder, the capacitor ladder to conduct multi-bit multiply and accumulate (MAC) operations during a computation phase, and controlling, by a successive approximation register (SAR) coupled to the capacitor ladder, the capacitor ladder to digitize results of the multi-bit MAC operations during a digitization phase.

Example 17 includes the method of Example 16, wherein the results of the multi-bit MAC operations are digitized via a comparator coupled to the capacitor ladder and the SAR.

Example 18 includes the method of Example 16, further including applying a rectified linear unit activation function to the digitized results.

Example 19 includes the method of any one of Examples 16 to 18, further including determining, by the SAR, a polarity of the results based on most significant bits in the results.

Example 20 includes the method of Example 19, further including bypassing, by the SAR, digitization of least significant bits in the results if the polarity is negative, and completing, by the SAR, digitization of the least significant bits in the results if the polarity is positive.

Example 21 includes an apparatus comprising means for performing the method of any one of Examples 16 to 20.

Embodiments may be implemented in one or more modules as a set of logic instructions stored in a machine- or computer-readable storage medium such as random access memory (RAM), read only memory (ROM), programmable ROM (PROM), firmware, flash memory, etc., in hardware, or any combination thereof. For example, hardware implementations may include configurable logic, fixed-functionality logic, or any combination thereof. Examples of configurable logic (e.g., configurable hardware) include suitably configured programmable logic arrays (PLAs), field programmable gate arrays (FPGAs), complex programmable logic devices (CPLDs), and general purpose microprocessors. Examples of fixed-functionality logic (e.g., fixed-functionality hardware) include suitably configured application specific integrated circuits (ASICs), combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a network controller; and
a processor coupled to the network controller, wherein the processor includes logic coupled to one or more substrates, the logic including:
a capacitor ladder,
a plurality of memory cells coupled to the capacitor ladder, the plurality of memory cells to control the capacitor ladder to conduct multi-bit multiply and accumulate (MAC) operations during a computation phase, and
a successive approximation register (SAR) coupled to the capacitor ladder, the SAR to control the capacitor ladder to digitize results of the multi-bit MAC operations during a digitization phase.

2. The computing system of claim 1, wherein the logic further includes a comparator coupled to the capacitor ladder and the SAR, wherein the results of the multi-bit MAC operations are to be digitized via the comparator.

3. The computing system of claim 1, wherein the logic is to apply a rectified linear unit activation function to the digitized results.

4. The computing system of claim 1, wherein the SAR is to determine a polarity of the results based on most significant bits in the results.

5. The computing system of claim 4, wherein the SAR is to bypass digitization of least significant bits in the results if the polarity is negative.

6. The computing system of claim 4, wherein the SAR is to complete digitization of least significant bits in the results if the polarity is positive.

7. The computing system of claim 1, wherein the capacitor ladder includes a C-2C ladder.

8. A semiconductor apparatus comprising:
one or more substrates; and
logic coupled to the one or more substrates, wherein the logic is implemented at least partly in one or more of configurable or fixed-functionality hardware, the logic including:
a capacitor ladder;
a plurality of memory cells coupled to the capacitor ladder, the plurality of memory cells to control the capacitor ladder to conduct multi-bit multiply and accumulate (MAC) operations during a computation phase; and
a successive approximation register (SAR) coupled to the capacitor ladder, the SAR to control the capacitor ladder to digitize results of the multi-bit MAC operations during a digitization phase.

9. The semiconductor apparatus of claim 8, further including a comparator coupled to the capacitor ladder and the SAR, wherein the results of the multi-bit MAC operations are to be digitized via the comparator.

10. The semiconductor apparatus of claim 8, wherein the logic is to apply a rectified linear unit activation function to the digitized results.

11. The semiconductor apparatus of claim 8, wherein the SAR is to determine a polarity of the results based on most significant bits in the results.

12. The semiconductor apparatus of claim 11, wherein the SAR is to bypass digitization of least significant bits in the results if the polarity is negative.

13. The semiconductor apparatus of claim 11, wherein the SAR is to complete digitization of least significant bits in the results if the polarity is positive.

14. The semiconductor apparatus of claim 8, wherein the capacitor ladder includes a C-2C ladder.

15. The semiconductor apparatus of claim 8, wherein the logic coupled to the one or more substrates includes transistor channel regions that are positioned within the one or more substrates.

16. A method comprising:
controlling, by a plurality of memory cells coupled to a capacitor ladder, the capacitor ladder to conduct multi-bit multiply and accumulate (MAC) operations during a computation phase; and
controlling, by a successive approximation register (SAR) coupled to the capacitor ladder, the capacitor ladder to digitize results of the multi-bit MAC operations during a digitization phase.

17. The method of claim 16, wherein the results of the multi-bit MAC operations are digitized via a comparator coupled to the capacitor ladder and the SAR.

18. The method of claim 16, further including applying a rectified linear unit activation function to the digitized results.

19. The method of claim 16, further including determining, by the SAR, a polarity of the results based on most significant bits in the results.

20. The method of claim 19, further including:
bypassing, by the SAR, digitization of least significant bits in the results if the polarity is negative; and
completing, by the SAR, digitization of the least significant bits in the results if the polarity is positive.
